(19) United States
(12) Patent Application Publication
(10) Pub. No.: US 2022/0121106 A1
(43) Pub. Date: Apr. 21, 2022

(54) METHODS OF FABRICATING PHASE SHIFT PHOTOMASKS

(71) Applicant: SK hynix Inc., Icheon-si Gyeonggi-do (KR)

(72) Inventors: Choong Han RYU, Cheongju-si Chungcheongbuk-do (KR); Tae Joong HA, Daejeon (KR)

(73) Assignee: SK hynix Inc., Icheon-si Gyeonggi-do (KR)

(21) Appl. No.: 17/562,665

(22) Filed: Dec. 27, 2021

Related U.S. Application Data
(62) Division of application No. 16/281,771, filed on Feb. 21, 2019.

(30) Foreign Application Priority Data
May 18, 2018 (KR) 10-2018-0057453

(51) Int. Cl. G03F 1/32

(52) U.S. Cl. CPC G03F 1/32

(57) ABSTRACT

A method of fabricating a phase shift photomask (PSM) includes providing a blank phase shift photomask including a phase shift layer, a light blocking layer, and a resist layer, patterning the resist layer of the PSM, removing a portion of the light blocking layer, removing the resist layer, and removing the portion of the phase shift layer using an etch process. The etch process is performed using a pulse power supply technique for which on and off operations of an alternating current (AC) power are alternately and repeatedly executed.

### CROSS-REFERENCE TO RELATED APPLICATIONS

This application is a divisional application of U.S. patent application Ser. No. 16/281,771 filed on Feb. 21, 2019, which claims benefits of priority of Korean Application No. 10-2018-0057453, filed on May 18, 2018. The disclosure of each of the foregoing application is incorporated herein by references in its entirety.

### BACKGROUND

### 1. Technical Field

Various embodiments of the present disclosure relate to methods of fabricating the phase shift photomasks.

### 2. Related Art

Very large scale integrated (VLSI) circuits have been developed to realize fast and low-power semiconductor devices. In order to develop the VLSI circuits, various process techniques for forming fine patterns on a substrate may be required. The fine patterns may be firstly defined by a photolithography technique utilizing a photomask. The photomask may dominantly influence formation of the fine patterns.

The photomask may include a binary photomask and a halftone phase shift photomask. The binary photomask may be comprised of a light transmission portion and a light blocking portion, and the halftone phase shift photomask may be comprised of a light transmission portion and a light semi-transmission portion. In general, the halftone phase shift photomask may be configured to include a transparent substrate and a plurality of phase shift patterns disposed on the transparent substrate. The plurality of phase shift patterns may transmit only a portion of light irradiated toward the transparent substrate. The halftone phase shift photomask may be designed such that an exposure light penetrating each of the phase shift patterns has an inverted phase of an exposure light penetrating only the transparent substrate.

### SUMMARY

According to an embodiment, a method of fabricating a phase shift photomask includes providing a blank phase shift photomask including a phase shift layer, a light blocking layer, and a resist layer sequentially stacked on a surface of a transparent substrate. The phase shift layer has a transmittance of between approximately 60% to approximately 90% and provides a phase difference of between approximately 180 degrees to approximately 250 degrees. The method also includes patterning the resist layer to form a resist pattern having an opening that exposes a portion of the light blocking layer. The method further includes removing the portion of the light blocking layer exposed by the opening of the light blocking layer to form a light blocking pattern exposing a portion of the phase shift layer. The method additionally includes removing the resist pattern and removing the portion of the phase shift layer exposed by the light blocking pattern using an etch process to form a phase shift pattern exposing a portion of the transparent substrate. The etch process is performed using a pulse power supply technique that on and off operations of an alternating current (AC) power are alternately and repeatedly executed.

### BRIEF DESCRIPTION OF THE DRAWINGS

Various embodiments of the present disclosure will become more apparent in view of the attached drawings and accompanying detailed description.

FIG. 1 shows a cross-sectional view illustrating a blank phase shift photomask, according to an embodiment of the present disclosure.

FIG. 2 shows a plan view illustrating a phase shift photomask, according to an embodiment of the present disclosure.

FIG. 3 shows a cross-sectional view taken along a line I-I′ of FIG. 2.

FIG. 4 shows a graph illustrating a normalized image logarithm slope (NILS) relative to a light transmittance of a phase shift photomask, according to an embodiment of the present disclosure.

FIG. 5 shows a graph illustrating a normalized image logarithm slope (NILS) relative to a phase difference of a phase shift photomask, according to an embodiment of the present disclosure.

FIG. 6 illustrates a slope of a light intensity at a boundary region between an exposed portion of a transparent substrate and a phase shift pattern on the transparent substrate according to a light transmittance of a phase shift photomask, in accordance with an embodiment of the present disclosure.

FIG. 7 illustrates a profile of photoresist patterns formed on a wafer using a phase shift photomask together with a profile of photoresist patterns formed on a wafer using a general phase shift photomask.

FIGS. 8 to 10 show cross-sectional views illustrating a method of fabricating a phase shift photomask, according to an embodiment of the present disclosure.

### DETAILED DESCRIPTION

In the following description of embodiments, it will be understood that the terms “first” and “second” are intended to distinguish similar elements and not used to define a single element or to imply a particular sequence or a hierarchy of importance. In addition, when an element is referred to as being located “on,” “over,” “above,” “under,” or “beneath” another element, it is intended to mean a relative positional relationship and not used to limit to a particular case for which the element either directly or indirectly contacts the other element via intervening elements. Accordingly, the terms such as “on,” “over,” “above,” “under,” “beneath,” “below,” and the like that are used herein are for the purpose of describing particular embodiments only and are not intended to limit the scope of the present disclosure. Further, when an element is referred to as being “connected” or “coupled” to another element, the element may be electrically or mechanically connected or coupled to the other element either directly or indirectly with other intervening elements.

Various embodiments are directed to methods of fabricating phase shift photomasks.

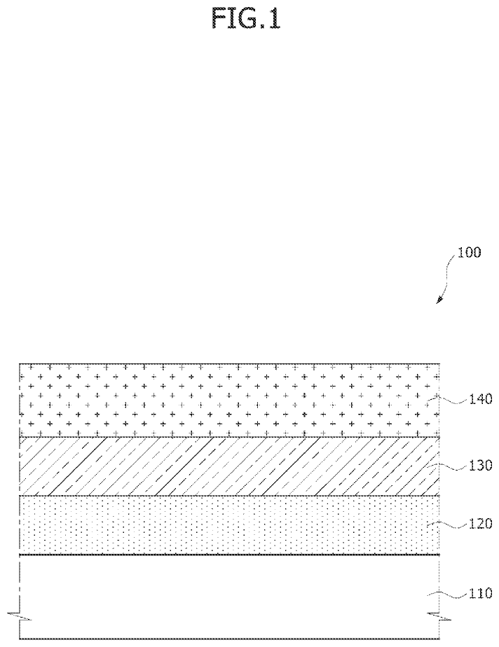

FIG. 1 shows a cross-sectional view illustrating a blank phase shift photomask 100, according to an embodiment of the present disclosure. Referring to FIG. 1, the blank phase shift photomask 100 may include a transparent substrate 110, a phase shift layer 120 disposed on a surface of the transparent substrate 110, a light blocking layer 130 disposed on a surface of the phase shift layer 120 opposite to the transparent substrate 110, and a resist layer 140 disposed on a surface of the light blocking layer 130 opposite to the phase shift layer 120. In an embodiment, the transparent substrate 110 may include a transparent material, for example, a quartz material, a glass material, a silicon material, a silicon nitride material, or an oxynitride material. In an embodiment, the light blocking layer 130 may include a chrome (Cr) material. The light blocking layer 130 may have a thickness of approximately nanometers to approximately 70 nanometers. In other embodiments, however, the light blocking layer 130 may have a thickness of less than 50 nanometers or greater than 70 nanometers. In an embodiment, the resist layer 140 may have a thickness of approximately 160 nanometers to approximately 170 nanometers. In other embodiments, however, the resist layer 140 may have a thickness of less than 160 nanometers or greater than 170 nanometers.

The phase shift layer 120 may include a material that changes a phase of light penetrating the material. In an embodiment, the phase shift layer 120 may include a material having a light transmittance of approximately 60% to approximately 90% and provide a phase difference of approximately 180 degrees to approximately 250 degrees. The phase difference of the phase shift layer 120 means a difference between a phase of light vertically penetrating the transparent substrate 110 to reach a bottom surface of the phase shift layer 120 and a phase of light vertically penetrating the phase shift layer 120 to reach a top surface of the phase shift layer 120 opposite to the transparent substrate 110. In an embodiment, the phase shift layer 120 may be formed of a silicon oxynitride (SiON) layer. In such a case, so that the phase shift layer 120 has a light transmittance of approximately 60% to approximately 90% and provides a phase difference of approximately 180 degrees to approximately 250 degrees, the compositions of silicon (Si), oxygen (O), and nitrogen (N) included in the phase shift layer 120 and a thickness of the phase shift layer 120 may be adjusted. In an embodiment, a composition ratio of silicon (Si), oxygen (O), and nitrogen (N) contained in the phase shift layer 120 may be approximately 1:0.2:1.2, and the phase shift layer 120 may have a thickness of approximately 112 nanometers to approximately 156 nanometers. A ratio of approximately 1:0.2:1.2 includes ratios that deviate from the indicated ratio by less than 5%. In another embodiment, a composition ratio of silicon (Si), oxygen (O), and nitrogen (N) contained in the phase shift layer 120 may be approximately 1:0.8:0.8, and the phase shift layer 120 may have a thickness of approximately 140 nanometers to approximately 193 nanometers. A ratio of approximately 1:0.8:0.8 includes ratios that deviate from the indicated ratio by less than 5%. In either case, the phase shift layer 120 may be provided to have a normalized image logarithm slope (NILS) of 2.08 to 3.00. The NILS denotes a variation of a light intensity at an edge of a pattern (formed of the phase shift layer 120). The NILS may be calculated by multiplying a logarithm slope of a light intensity at an edge of a pattern by a target line width to normalize. Thus, increase of the NILS means improvement of resolution at an edge of the pattern.

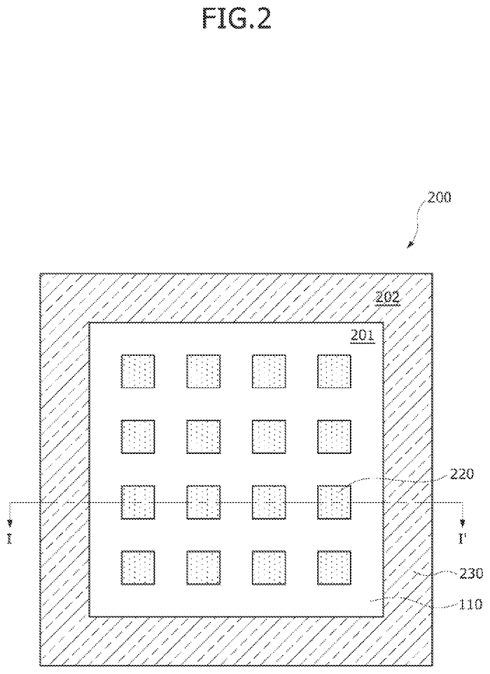

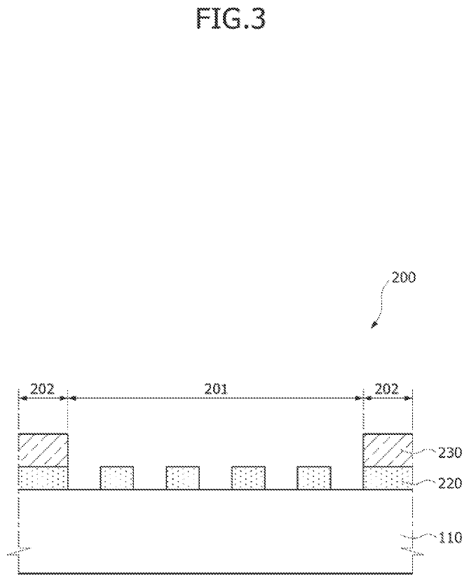

FIG. 2 shows a plan view illustrating a phase shift photomask 200, according to an embodiment of the present disclosure, and FIG. 3 shows a cross-sectional view taken along a line I-I′ of FIG. 2. Referring to FIGS. 2 and 3, the phase shift photomask 200 may include a pattern transfer region 201 and a frame region 202. The frame region 202 may be disposed to surround the pattern transfer region 201, as shown in the plan view. A plurality of transfer patterns may be disposed in the pattern transfer region 201. A light blocking pattern 230 may be disposed in the frame region 202. The phase shift photomask 200 in the pattern transfer region 201 may include a plurality of phase shift patterns 220 disposed on a portion of the transparent substrate 110. Each of the phase shift patterns 220 may act as transfer patterns. The transfer patterns may be defined as patterns whose images are transferred onto a photoresist layer coated on a wafer by a photolithography process. The phase shift photomask 200 in the frame region 202 may include the phase shift pattern 220 and the light blocking pattern 230, which are sequentially stacked on another portion of the transparent substrate 110.

In an embodiment, the transparent substrate 110 may include a transparent material, for example, a quartz material, a glass material, a silicon material, a silicon nitride material, or an oxynitride material. Each of the phase shift patterns 220 may include a material that changes a phase of light penetrating the material. In an embodiment, each of the phase shift patterns 220 may include a material having a light transmittance of approximately 60% to approximately 90% and provide a phase difference of approximately 180 degrees to approximately 250 degrees. The phase difference of the phase shift patterns 220 means a difference between a phase of light vertically penetrating the transparent substrate 110 to reach bottom surfaces of the phase shift patterns 220 and a phase of light vertically penetrating the phase shift patterns 220 to reach top surfaces of the phase shift patterns 220 opposite to the transparent substrate 110. In an embodiment, the phase shift patterns 220 may be formed of a silicon oxynitride (SiON) layer. In such a case, so that the phase patterns 220 have a light transmittance of approximately 60% to approximately 90% and provide a phase difference of approximately 180 degrees to approximately 250 degrees, the compositions of silicon (Si), oxygen (O), and nitrogen (N) included in each of the phase shift patterns 220 and a thickness of the phase shift patterns 220 may be adjusted. In an embodiment, a composition ratio of silicon (Si), oxygen (O), and nitrogen (N) contained in each of the phase shift patterns 220 may be approximately 1:0.2:1.2, and each of the phase shift patterns 220 may have a thickness of approximately 112 nanometers to approximately 156 nanometers. In another embodiment, a composition ratio of silicon (Si), oxygen (O), and nitrogen (N) contained in each of the phase shift patterns 220 may be approximately 1:0.8:0.8, and each of the phase shift patterns 220 may have a thickness of approximately 140 nanometers to approximately 193 nanometers. In either case, the phase shift patterns 220 may be provided to have a normalized image logarithm slope (NILS) of 2.08 to 3.00. In an embodiment, the light blocking pattern 230 may include a chrome (Cr) material. The light blocking pattern 230 may have a thickness of approximately 50 nanometers to approximately 70 nanometers.

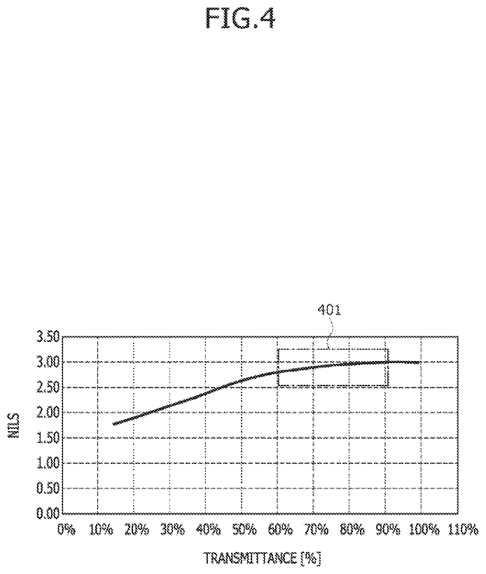

FIG. 4 shows a graph illustrating the normalized image logarithm slope (NILS) relative to a light transmittance of each of the phase shift patterns 220 included in the phase shift photomask 200 described with reference to FIGS. 2 and 3. Referring to FIG. 4, each of the phase shift patterns 220 may have a light transmittance of approximately 60% to approximately 90%. Thus, as illustrated in a portion 401 of FIG. 4, the NILS may have a value of approximately 2.8 if each of the phase shift patterns 220 has a light transmittance of approximately 60%, and the NILS may gradually increase if a light transmittance of the phase shift patterns 220 increases from 60%. If each of the phase shift patterns 220 has a light transmittance of approximately 90%, the NILS may be close to approximately 3.0. If a light transmittance of the phase shift patterns 220 is over 90%, the NILS may be saturated and not increase. Accordingly, in case of the phase shift photomask 200, the NILS may have a value of approximately 2.8 to approximately 3.0. As a result, a slope of a light intensity at an edge of the phase shift pattern 220 may be steepest.

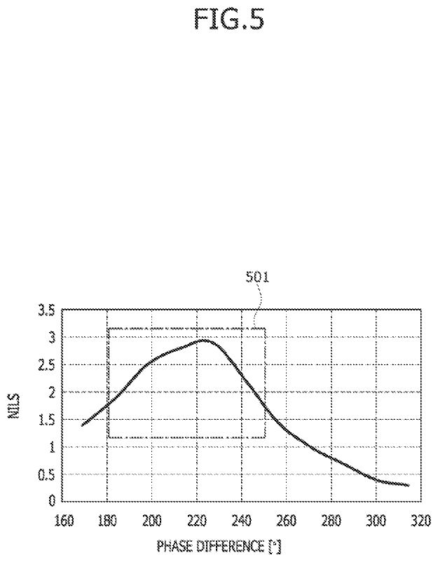

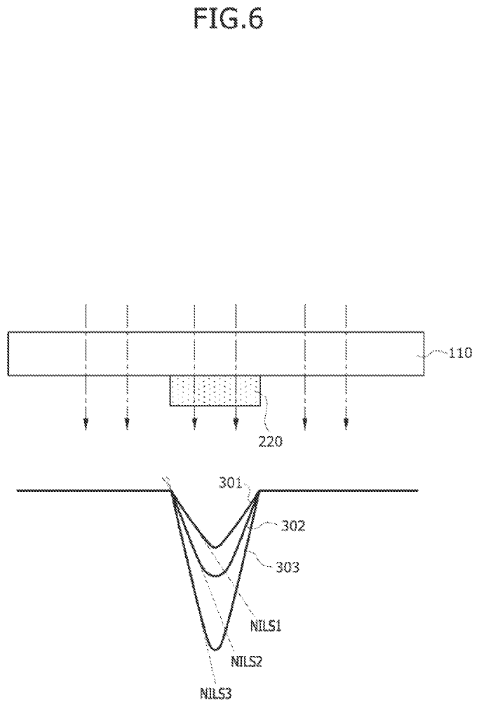

FIG. 5 shows a graph illustrating the normalized image logarithm slope (NILS) relative to a phase difference of the phase shift photomask 200 described with reference to FIGS. 2 and 3. Referring to FIG. 5, each of the phase shift patterns 220 included in the phase shift photomask 200 may be formed to provide a phase difference of approximately 180 degrees to approximately 250 degrees. That is, a phase of light vertically incident onto the phase shift pattern 220 may precede a phase of light vertically passing through the phase shift pattern 220 by approximately 180 degrees to approximately 250 degrees. Thus, as illustrated in a portion 501 of FIG. 5, the NILS may have a maximum value of approximately 3.0 if the phase shift patterns 220 provide a phase difference of approximately 220 degrees. The NILS may have a relatively high value if the phase shift patterns 220 provide a phase difference of approximately 180 degrees to approximately 250 degrees. FIG. 6 illustrates a slope of a light intensity at a boundary region between an exposed portion of the transparent substrate 110 and an edge of the phase shift pattern 220, as shown in the plan view, according to a light transmittance of the phase shift pattern 220 of the phase shift photomask 200 described with reference to FIGS. 2 and 3. In FIG. 6, the same reference numerals as used in FIGS. 2 and 3 denote the same elements. In FIG. 6, a curve 303 denotes a case for which each of the phase shift patterns 220 has a light transmittance of approximately 80%. Moreover, a curve 301 denotes a case for which a phase shift pattern has a light transmittance of approximately 6%, and a curve 302 denotes a case for which a phase shift pattern has a light transmittance of approximately 18%. As can be seen from FIG. 6, a NILS (see a slope of a dotted line ‘NILS2’) when the phase shift pattern has a light transmittance of approximately 6% is greater than a NILS (see a slope of a dotted line ‘NILS1’) when the phase shift pattern has a light transmittance of approximately 18%. In addition, the NILS (see a slope of a dotted line ‘NILS3’) when the phase shift pattern 220 has a light transmittance of approximately 80% is greater than the NILS1 when the phase shift pattern has a light transmittance of approximately 6% and the NILS2 when the phase shift pattern has a light transmittance of approximately 18%. This means that a slope of a light intensity at a boundary region between the phase shift pattern 220 having a light transmittance of approximately 80% and the transparent substrate 110, as shown in the plan view, is greater than other cases for which the phase shift pattern has a light transmittance of approximately 6% and the phase shift pattern has a light transmittance of approximately 8%.

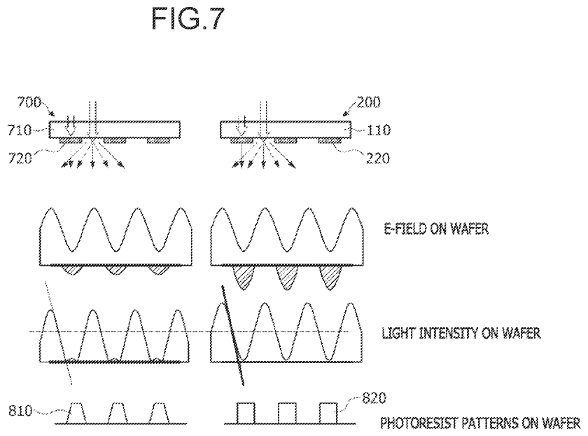

FIG. 7 illustrates a profile of photoresist patterns 820 formed on a wafer using the phase shift photomask 200, according to an embodiment of the present disclosure, together with a profile of photoresist patterns 810 formed on a wafer using a general phase shift photomask 700. Referring to FIG. 7, each of the phase shift patterns 220 of the phase shift photomask 200 has a light transmittance of approximately 60% to approximately 90% and provides a phase difference of approximately 180 degrees to approximately 250 degrees, and each of phase shift patterns 720 of the general shift photomask 700 has a light transmittance of approximately 6% and provides a phase difference of approximately 180 degrees. As a result, an electric field (E-field) of light penetrating the phase shift patterns 220 to exhibit a phase difference of approximately 180 degrees to approximately 250 degrees on a wafer during a photolithography process performed with the phase shift photomask 200 may be higher than an E-field of light penetrating the phase shift patterns 720 to exhibit a phase difference of approximately 180 degrees on a wafer during a photolithography process performed with the general phase shift photomask 700. Thus, for light intensity on a wafer, a slope of the light intensity at a boundary region between the transparent substrate 110 and the phase shift pattern 220 in a plan view may be greater (or steeper) than a slope of the light intensity at a boundary region between the transparent substrate 710 and the phase shift pattern 720 in a plan view. Accordingly, while side surfaces of the photoresist patterns 720 formed on a wafer using the general phase shift photomask 700 have an inclined profile, side surfaces of the photoresist patterns 820 formed on a wafer using the phase shift photomask 800 may have a relatively more vertical profile.

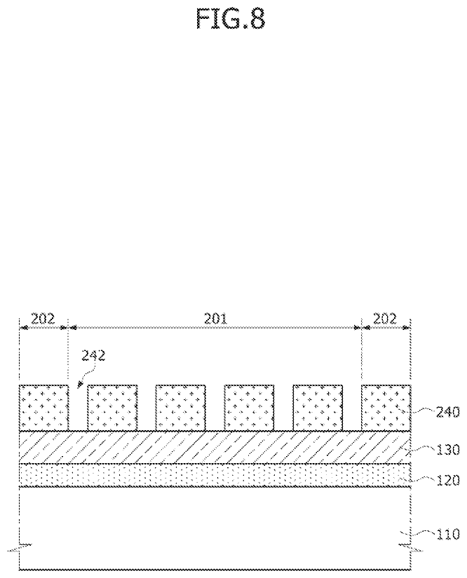

FIGS. 8 to 10 show cross-sectional views illustrating a method of fabricating a phase shift photomask, according to an embodiment of the present disclosure. First, the blank phase shift photomask 100 illustrated in FIG. 1 may be provided. As described with reference to FIG. 1, the blank phase shift photomask 100 may include the phase shift layer 120, the light blocking layer 130, and the resist layer 140 sequentially stacked on the transparent substrate 110. In an embodiment, the transparent substrate 110 may include a transparent material, for example, a quartz material, a glass material, a silicon material, a silicon nitride material, or an oxynitride material. In an embodiment, the light blocking layer 130 may include a chrome (Cr) material. The light blocking layer 130 may have a thickness of approximately 50 nanometers to approximately 70 nanometers. In an embodiment, the resist layer 140 may have a thickness of approximately 160 nanometers to approximately 170 nanometers.

The phase shift layer 120 may include a material that changes a phase of light penetrating the material. In an embodiment, the phase shift layer 120 may include a material having a light transmittance of approximately 60% to approximately 90% and provide a phase difference of approximately 180 degrees to approximately 250 degrees. The phase difference of the phase shift layer 120 means a difference between a phase of light vertically penetrating the transparent substrate 110 to reach a bottom surface of the phase shift layer 120 and a phase of light vertically penetrating the phase shift layer 120 to reach a top surface of the phase shift layer 120 opposite to the transparent substrate 110. In an embodiment, the phase shift layer 120 may be formed of a silicon oxynitride (SiON) layer. In such a case, in order that the phase shift layer 120 has a light transmittance of approximately 60% to approximately 90% and provides a phase difference of approximately 180 degrees to approximately 250 degrees, it may be necessary to appropriately adjust compositions of silicon (Si), oxygen (O), and nitrogen (N) contained in the phase shift layer 120 and a thickness of the phase shift layer 120. In an embodiment, a composition ratio of silicon (Si), oxygen (O), and nitrogen (N) contained in the phase shift layer 120 may be approximately 1:0.2:1.2, and the phase shift layer 120 may have a thickness of approximately 112 nanometers to approximately 156 nanometers. In another embodiment, a composition ratio of silicon (Si), oxygen (O), and nitrogen (N) contained in the phase shift layer 120 may be approximately 1:0.8:0.8, and the phase shift layer 120 may have a thickness of approximately 140 nanometers to approximately 193 nanometers. In either case, the phase shift layer 120 may be provided to have a normalized image logarithm slope (NILS) of 2.08 to 3.00.

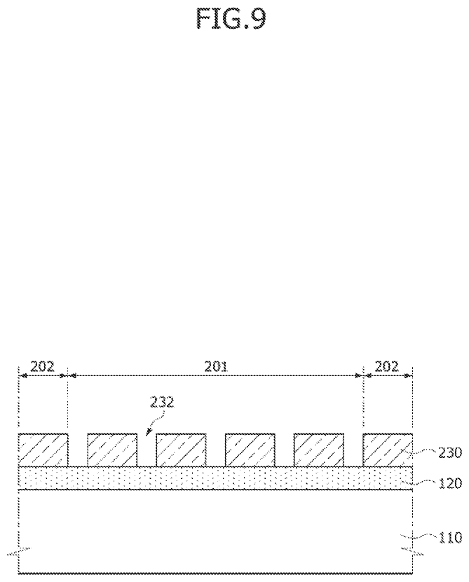

As illustrated in FIG. 8, the resist layer (140 of FIG. 1) may be patterned to form resist patterns 240 defining openings 242 that expose portions of the light blocking layer 130. For an embodiment, the openings 242 defined by the resist patterns 240 are disposed only in a pattern transfer region (corresponding to the pattern transfer region 201 of FIGS. 2 and 3) of the blank phase shift photomask 100, and any one of the resist patterns 240 may be formed to cover the light blocking layer 130, which is located in a frame region (corresponding to the frame region 202 of FIGS. 2 and 3) of the blank phase shift photomask 100. As illustrated in FIG. 9, portions of the light blocking layer 130 exposed by the resist patterns (240 of FIG. 8) may be selectively removed to form light blocking patterns 230. The light blocking patterns 230 may have openings 232 that expose portions of the phase shift layer 120. After the light blocking patterns 230 are formed, the resist patterns (240 of FIG. 8) may be removed.

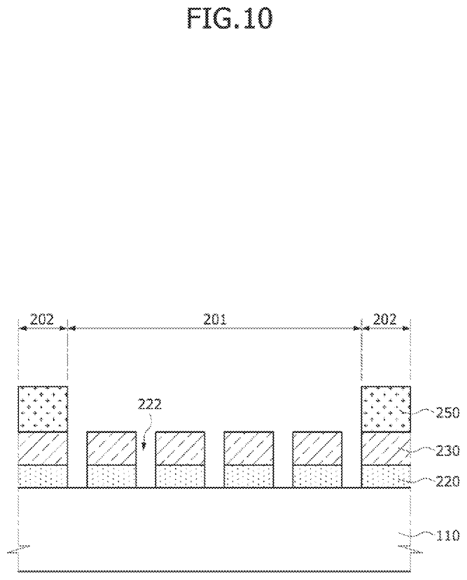

As illustrated in FIG. 10, portions of the phase shift layer (120 of FIG. 9) exposed by the light blocking patterns 230 may be removed to form the phase shift patterns 220. The exposed portions of the phase shift layer (120 of FIG. 9) may be removed using an etch process. The phase shift patterns 220 may be formed to have openings 222 that expose portions of the transparent substrate 110. In order to perform an etch process for forming the phase shift patterns 220, the transparent substrate 110 on which the light blocking patterns (230 of FIG. 9) are formed may be loaded into a dry etch apparatus. Thereafter, an alternating current (AC) power may be supplied to a source of the dry etch apparatus to perform a dry etch process for removing the exposed portions of the phase shift layer (120 of FIG. 9). In such a case, the AC power may be applied to the source of the dry etch apparatus using a pulse power supply technique that on and off operations of the AC power are alternately and repeatedly executed like a pulse waveform. In the method of fabricating a phase shift photomask according to an embodiment, the phase shift layer (120 of FIG. 9) may be provided to have a light transmittance of approximately 60% to approximately 90% and to exhibit a phase difference of approximately 180 degrees to approximately 250 degrees. Thus, if the phase shift patterns 220 are formed using a general continuous power supply technique that an AC power is continuously applied to an etch apparatus, the transparent substrate 110 adjacent to the phase shift patterns 220 may also be etched to form trenches in the transparent substrate 110. Accordingly, in the method of fabricating a phase shift photomask according to an embodiment, the phase shift patterns 220 may be formed using the pulse power supply technique to prevent trenches from being formed in the transparent substrate 110 during the etch process for forming the phase shift patterns 220.

After the phase shift patterns 220 are formed, a resist pattern 250 may be formed to expose an entire portion of the pattern transfer region 201 and to cover the frame region 202. The light blocking patterns 230 in the pattern transfer region 201 may be selectively removed by an etch process that is performed using the resist pattern 250 as an etch mask. As a result, the phase shift patterns 220 in the pattern transfer region 201 may be completely exposed. The resist pattern 250 may then be removed to fabricate the phase shift photomask 200 illustrated in FIGS. 2 and 3.

A limited number of possible embodiments for the present disclosure have been disclosed above for illustrative purposes. Those of ordinary skill in the art will appreciate that various modifications, additions, and substitutions are possible, without departing from the scope and spirit of the present disclosure as disclosed in the accompanying claims.

What is claimed is:

1. A method of fabricating a phase shift photomask, the method comprising:
providing a blank phase shift photomask including a phase shift layer, a light blocking layer, and a resist layer sequentially stacked on a surface of a transparent substrate, wherein the phase shift layer has a transmittance of between approximately 60% to approximately 90% and provides a phase difference of between approximately 180 degrees to approximately 250 degrees;
patterning the resist layer to form a resist pattern having an opening that exposes a portion of the light blocking layer;
removing the portion of the light blocking layer exposed by the opening of the light blocking layer to form a light blocking pattern exposing a portion of the phase shift layer;
removing the resist pattern; and
removing the portion of the phase shift layer exposed by the light blocking pattern using an etch process to form a phase shift pattern exposing a portion of the transparent substrate,
wherein the etch process is performed using a pulse power supply technique for which on and off operations of an alternating current (AC) power are alternately and repeatedly executed.

2. The method of claim 1, wherein the phase shift layer includes a silicon oxynitride (SiON) material.

3. The method of claim 2, wherein a composition ratio of silicon (Si), oxygen (O), and nitrogen (N) included in the silicon oxynitride (SiON) material is approximately 1:0.2:1.2.

4. The method of claim 3, wherein the silicon oxynitride (SiON) material has a thickness of between approximately 112 nanometers to approximately 156 nanometers.

5. The method of claim 2, wherein a composition ratio of silicon (Si), oxygen (O), and nitrogen (N) included in the silicon oxynitride (SiON) material is approximately 1:0.8:0.8.

6. The method of claim 5, wherein the silicon oxynitride (SiON) material has a thickness of between approximately 140 nanometers to approximately 193 nanometers.

7. The method of claim 1, wherein the phase shift layer has a normalized image logarithm slope (NILS) of between approximately 2.08 to approximately 3.00.
